(19) United States
(12) Patent Application Publication
(10) Pub. No.: US 2021/0049312 A1
(43) Pub. Date: Feb. 18, 2021

(54) Roofing Kit and Database

(71) Applicant: Stephen Rose, Aurora, CO (US)

(72) Inventor: Stephen Rose, Aurora, CO (US)

(21) Appl. No.: 16/991,215

(22) Filed: Aug. 12, 2020

Related U.S. Application Data
(60) Provisional application No. 62/885,756, filed on Aug. 12, 2019.

(51) Int. Cl. G06F 30/13; G06Q 50/16; G06F 16/9035; G06F 16/901; G06F 16/9038

(52) U.S. Cl. CPC G06F 30/13; G06Q 50/163; G06F 16/9038; G06F 16/901; G06F 16/9035

(57) ABSTRACT

A kit for facilitating recording shingle data into a shingle or roof database. The database is prepared for use on a remote server. The kit contains shingles, software, and shingle ID images. The software links the shingles to the database and an installer uses the software to record or enter data about the structure that will receive the shingles in the kit. Data about the structure can include location of the structure. The installer can record other data such as the date of installation.

### CROSS-REFERENCE TO RELATED APPLICATIONS

The present application is related to and claims priority to US Provisional Patent Application No. 62/885,756 filed Aug. 12, 2019, which is incorporated by reference here in its entirety.

### BACKGROUND OF THE INVENTION

The following includes information that may be useful in understanding the present disclosure. It is not an admission that any of the information provided herein is prior art nor material to the presently described or claimed inventions, nor that any publication or document that is explicitly or implicitly referenced is prior art.

The roof of a structure is sometimes the most expensive portion of the structure known to wear out before the structure wears out. One gauge of how much life is left in a roof is the roof's age. But age information is not easily verified. Since the roof's age indicates the time frame for future replacement, having accurate information about its age allows a more accurate valuation of the home during appraisals and more accurate valuations for insurance claim reimbursement.

### SUMMARY

In some versions, the device has a combination scanning and software system for roofing materials designed to identify the age and installation date of shingles. In this version, the system features a series of barcodes or chips, scannable using a smartphone or tablet with the software application installed, capable of displaying the exact date a roof was installed. These barcodes or chips can be embedded in or on the shingle or on the wrap or box the shingles are packaged in. Further, the system uses a subscription-based software application that allows inspectors, insurance underwriters, roofers, etc., to verify information regarding the roof system. This system also ensures that home buyers know when a roof was installed, as they evaluate purchasing the home. In use, the system offers a simple method to determine roof age, past manufacturing, and product information accurately.

### BRIEF DESCRIPTION OF THE DRAWINGS

The figures that accompany the written portion of this specification illustrate embodiments and methods of use for the present disclosure, a surface staining composition and method, constructed and operative according to the teachings of the present disclosure.

FIG. 1 is a schematic view of a structure being roofed with a shingle.

FIG. 2 is another view of the structure of FIG. 1.

FIG. 3 is a schematic view of the structure being roofed with a different shingle.

FIG. 4 is a schematic view of an electronic device.

FIG. 5 is a schematic view of an ID tag sheet.

FIG. 6 is a schematic view of an ID tag.

FIG. 7 is a flow chart of a method of roofing a structure.

FIG. 8 is a flow chart of a method of roofing age determination.

FIG. 9 is a flow chart related to a roofing database.

FIG. 10 is a flow chart related to the software application.

The various embodiments of the present invention will be described with the appended drawings, wherein like designations denote like elements.

### DETAILED DESCRIPTION

A roof database includes data from several different sources. The first data source is the shingle manufacturer. The manufacturer prepares the shingles and packages them with a wrapper or box that contains data fields that can connect the shingles with a roof database record. The roof database record comprises fields such as shingle color, shingle manufacturer, shingle class, manufacture date, manufacture ID, shingle type, product ID, origination ID, stated shipment destination, or a random ID (such as a serial number).

Another source of data for the roof database is the shingle installer. At the installation time and installation site, the software allows the installer to couple data from the manufacturer associated with a particular lot of shingles and communicates with the roof database to provide the installation address, the installation date, and information about who installed the product. This data matches to a record in the roof database.

Another source of data for the roof database is public real estate records such as records stored at an assessor's office or permitting office. This data can include information about the parcel number of the installation location, features of the home, such as the number of stories, type of home, the year built, roof type, lot size, etc.

Therefore, when the record is complete, it provides information about what kind of shingles are installed on the roof at a particular location and information about the nature of the shingles, the manufacturer, and other data and ties that data into the public real estate records.

The manufacturer makes the shingles. The shingles are boxed or wrapped and identified with some sort of ID recorded on the box of shingles. This identification will later be used to tie the box of shingles to a record containing information about the shingles. For instance, the manufacturer could mark the outside of the box with the QR code containing identification information readable by a software application. The software application would allow the installer to quickly provide installation data to the roof database. At the time of installation, the installer would record information about the address, the date, and the roofing company into the software and would then read the QR code or other ID to create the link between the installed shingles and manufacturer information about the shingles. In some versions, other software, such as server software, would link the installation location data with manufacturing shingle data and public records containing data about the structure and its location.

Once data like this is collected, it can serve many uses. For instance, the data could assist the manufacturer and homeowner in getting and providing warranty service. A real estate appraiser could query the roof database to receive information about the age of the roof and the quality of the shingles that were installed. Likewise, an insurance adjuster could query the roof database for similar information in determining appropriate payments under the insurance policy. Potential buyers could query the roof database to find out information about the age and quality of the roof, as well. The buyer could also query the roof database for information about who installed the roof should that information become useful.

In one version, the process begins with the installer scanning the code on the outside of a box of shingles. The software can then communicate that information to the roof database, at which time the information could be matched with pre-existing manufacturers record, or a new record could be created about the data from the installed.

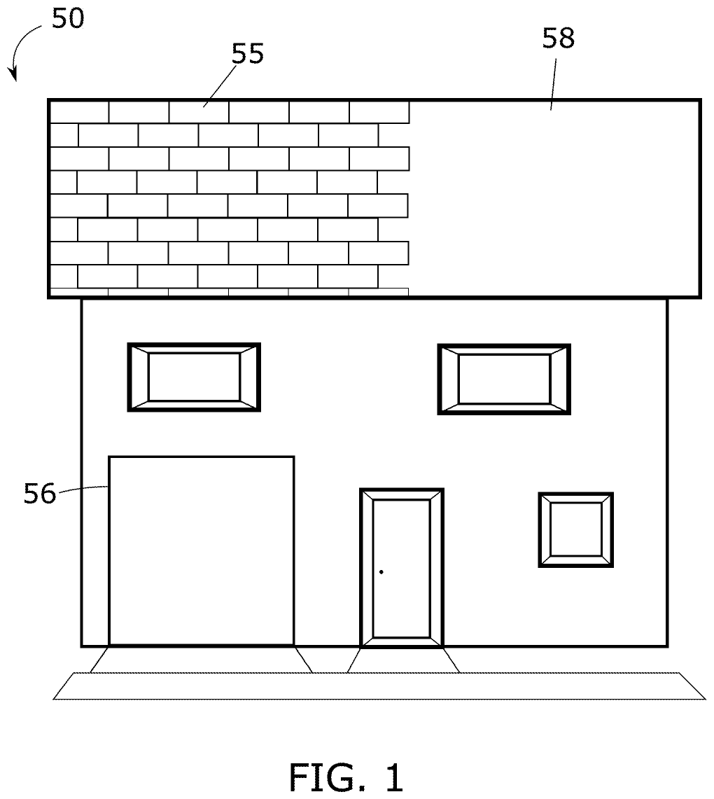

FIG. 1 depicts a standard structure 50. Structure 50 in this figure is a residential house that is roofed with roofing shingles 55. The figure also depicts garage door 56.

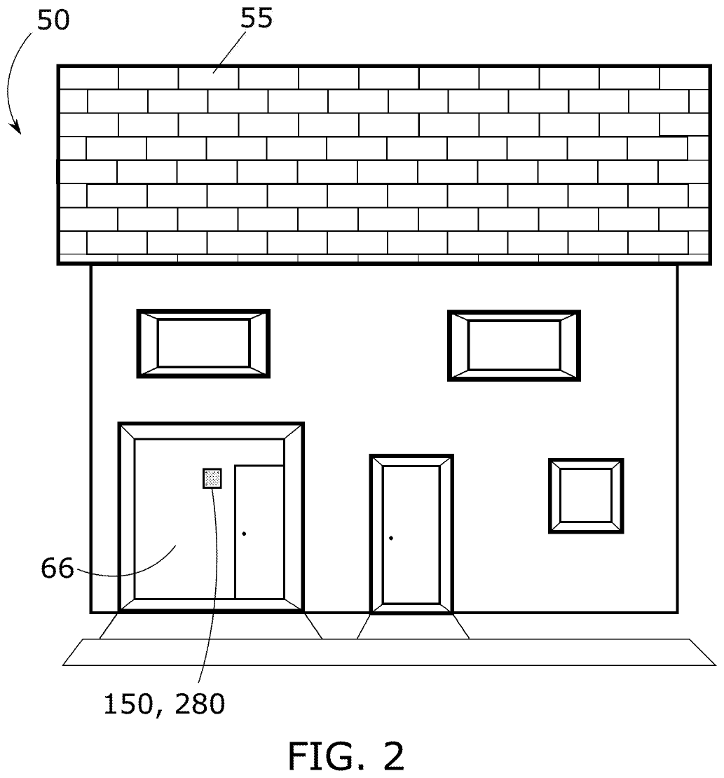

FIG. 2 depicts structure 50 from FIG. 1 during the process of applying roof shingles 55 to the roof. The shingling process is partial or complete with an unshingled portion 58 and a shingled portion. FIG. 2 also depicts exemplary box 60 of shingles 55. Box 60 has primary ID tag 150 on the outside. Box 60 also comprises ID tag sheet 165 comprising an additional version of primary ID tag 150, permanently installable (PI) ID tag 280, or both. FIG. 2 additionally depicts electronic device 160. Electronic device 160 is a special-purpose computer that has the functionality to read primary ID tag 150 and PI ID tag 280. Electronic device 160 has a user interface for receiving data and outputting data. Also, electronic device 160 comprises memory and has a wide area network (WAN) capabilities. In some versions, electronic device 160 is a cell phone or smartphone. Depending upon the version, primary ID tag 150 and PI ID tag 280 are replicas of each other, contain the same data as each other, or contain data similar to the data that the other tag contains. FIG. 2 shows the garage door open. Either primary ID tag 150 or PI ID tag 280 or both are mounted in the garage. In this case, on the garage wall 66.

Those of ordinary skill in the art will recognize that many different types of ways of storing data on ID tag 150 and PI ID tag 280 exist, including bar codes, QR codes, text encoding, magnetic encoding, optical encoding, as well as other now-existing or later-developed data encoding technologies.

In some versions, WAN capabilities include data communications transmitted wirelessly, such as through cellular data communications or other wireless technology. In some of these versions, WAN capabilities allow electronic device 160 to communicate over the Internet from the location of structure 50.

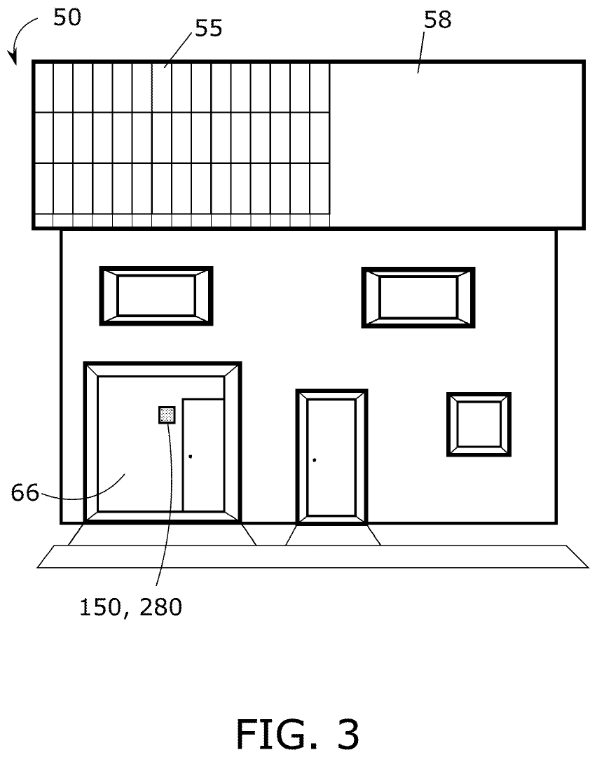

FIG. 3 depicts garage door 56 open, showing a view of back garage wall 66. A copy of PI ID tag 280 appears on back garage wall 66, in this version. FIG. 3 depicts structure 50 in the process of being roofed or shingled with a different type of shingles 55. Unshingled portion 58 is shown, as well.

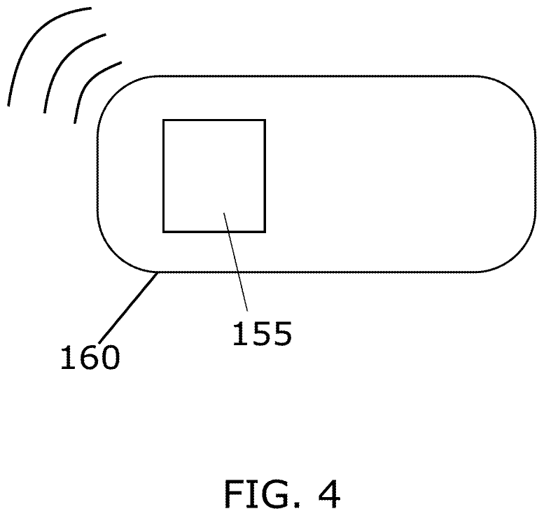

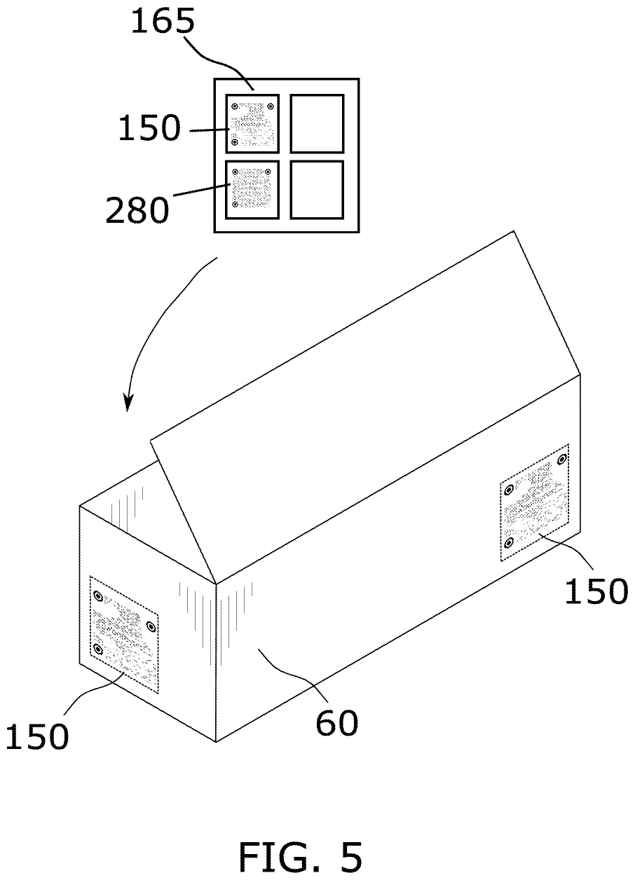

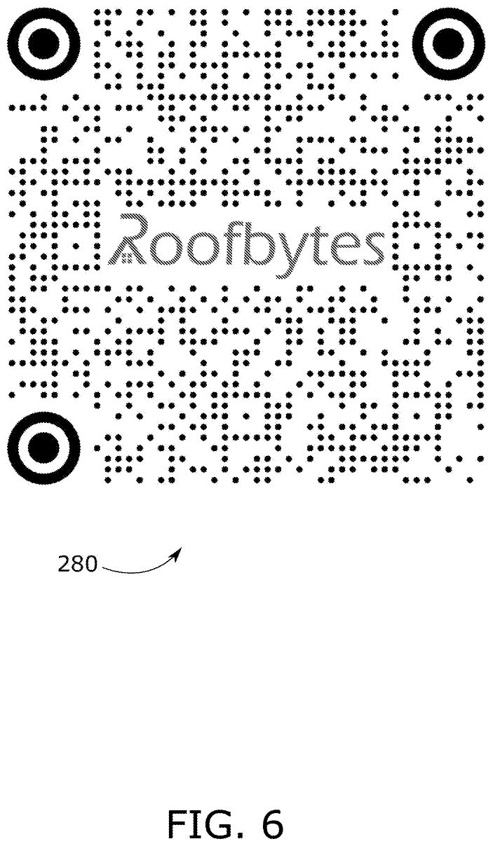

FIG. 4 depicts a schematic view of electronic device 160. Electronic device 160 has screen 155, in this version. Screen 155 is part of a user interface to electronic device 160. In this version, structure 50 has a different type of shingles 55. FIG. 5 shows sheet 165, which comprises an example of primary ID 150 or PI ID 280.

Shingles 55 are available in a variety of types such as asphalt, composite, Clay, Slate, wood, metal, etc. Data representing the type of shingle is called shingle-type data.

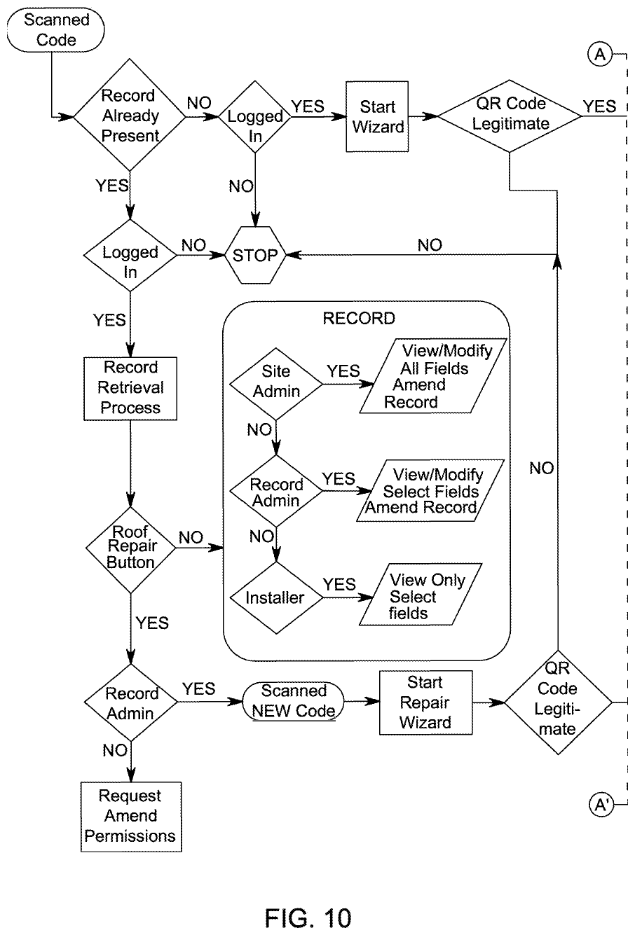

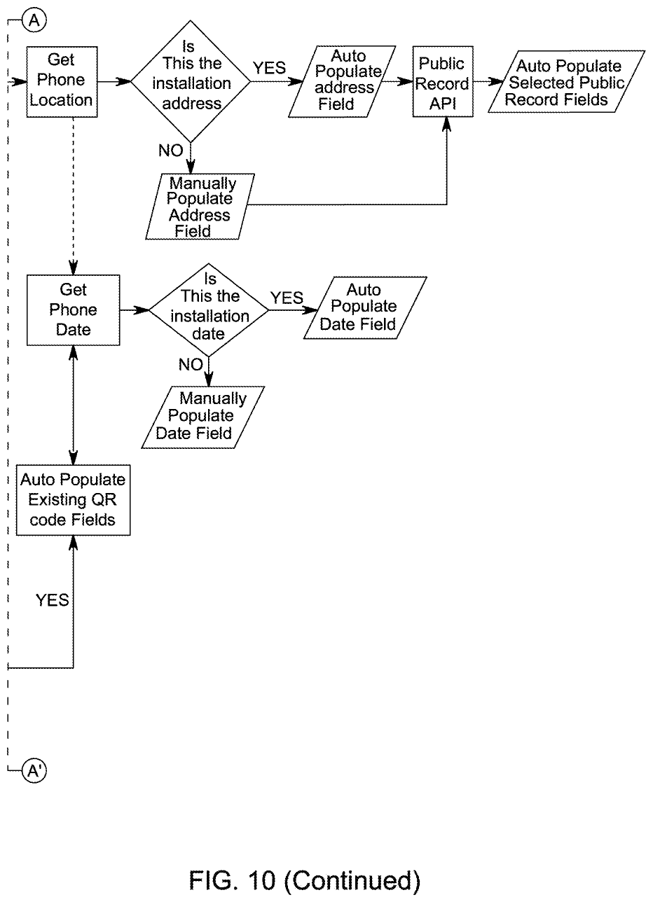

Electronic device 160 comprises or is adapted to comprise software instructions providing software functionality when executed. A version of the software application is depicted by the flowchart shown in FIG. 10.

Software functionality includes location-data input and shingle-type input functionality. Location-data input functionality includes retrieving location-data input from location subcomponents (GPS unit) inside of electronic device 160 or recording location-data input manually. In these or other versions, the software receives shingle-data input by using or reading primary ID tag 150 or PI ID tag 280. In some versions, electronic device 160 sends a data record over the WAN to a server computer. The data record links the location data and the shingle data. In some versions, the data record also links installation date data to the location data and the shingle data.

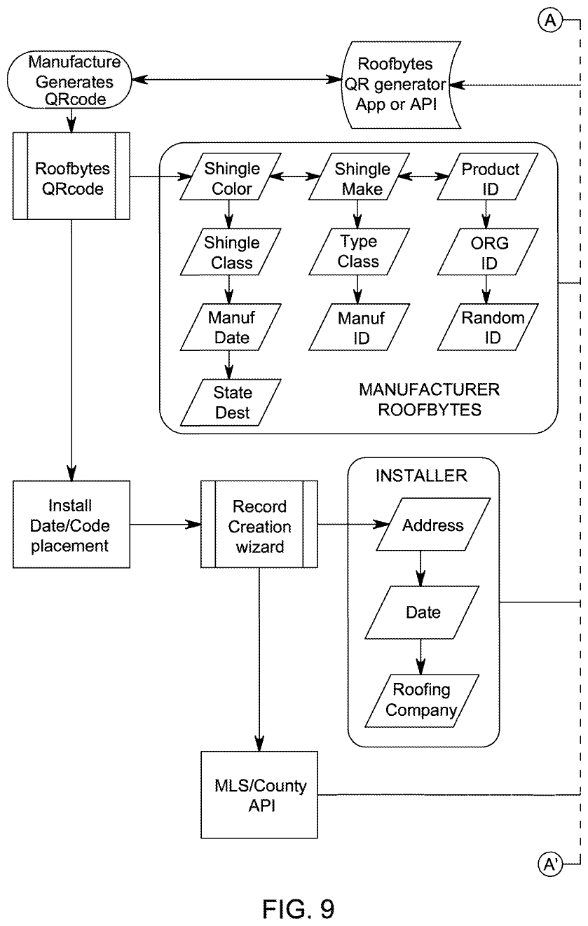

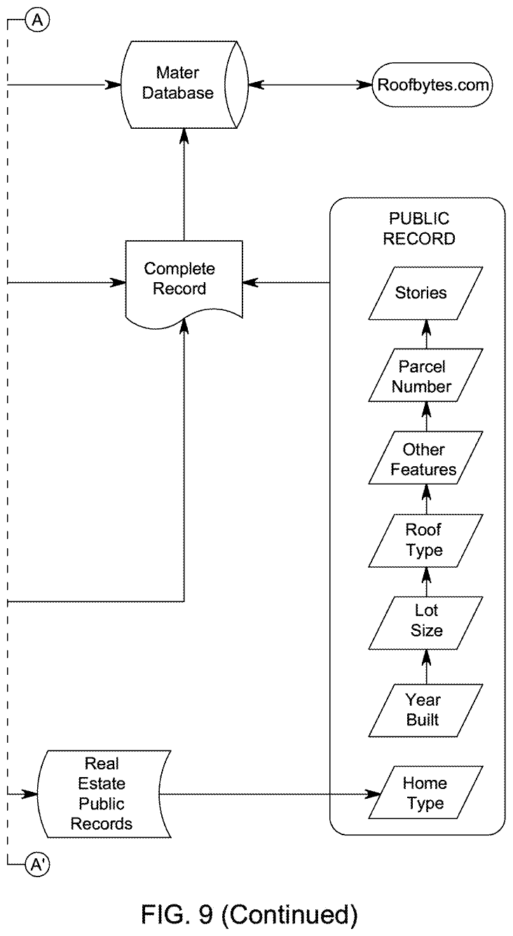

In some versions, software functionality includes data output of data records that the electronic device 160 receives from a server device, which contains information relevant to the shingles, location, and installation date. Sometimes this information is referred to as a record in a roof or roofing database. FIG. 9 depicts a flowchart describing the generation of the roof database.

In some versions, primary ID tag 150 includes data representing a link to a database containing information about shingles 55 contained in box 60. In some versions, PI ID tag 280 contains data representing a link to a database containing information about shingles 55 in box 60.

The roof database contained by the external server contains, in various versions, data from shingle manufacturers, data from the installer, data from public real estate title custodians. The roof database can contain data contributed by the manufacturer. Installer data can be input from the installer at the site of shingle 55 installation, which can link shingle data with real estate title data located in public records.

Shingles 55 can be installed with the barcode (primary ID Tag or PI ID Tag) present on the roof or on shingles 55, such as the underside of shingles 55. The barcode can be scanned using the software application to retrieve information about the age of the shingles and the installation date.

Roof age is an important factor when determining the value of a structure. But determining a real age for the roofing material or the actual quality of the shingles can be nearly impossible in some situations. And having to repair a roof shortly after purchasing a home can be immensely frustrating. Insurance underwriters may be unaware of how old a roof is and be unable to assign accurate property value to the home. A suitable solution is desired.

Disclosed is a system to verify age or material of roofing materials accurately. The system may include a device, such as a chip or a barcode, factory-installed into some of the shingles. The chip or barcode may hold information on the roof shingle, such as age, date of installation, material of the roof shingle, etc. Further, the system may include a subscription-based software application downloadable to a mobile device and used by inspectors, roofers, insurance companies, agents, etc. to verify information about the roof.

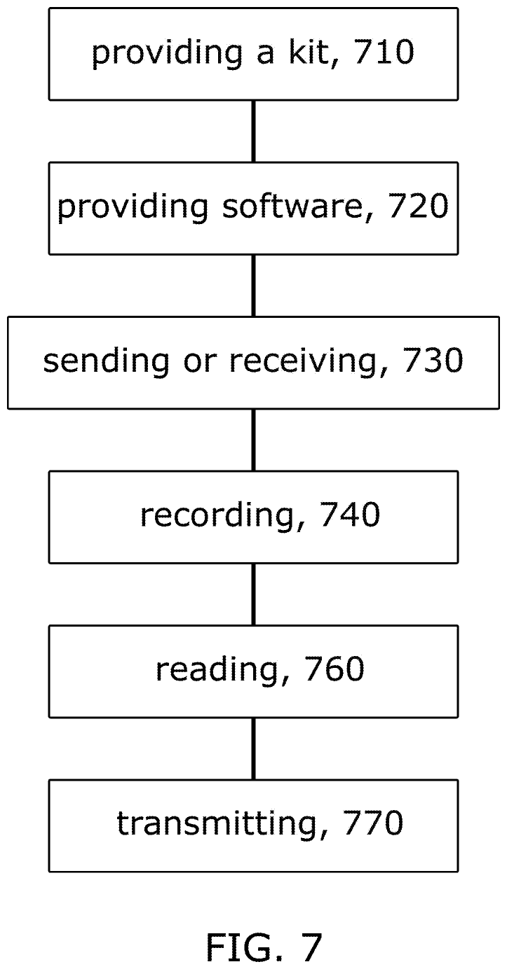

FIG. 7 depicts a method that comprises providing a kit 710 of the equipment described above. Additionally, the method comprises providing software 720 to end-user electronic device 160. In some versions, the software facilitates a step of sending or receiving 730 data from or to a first server roof database. Depending upon the version, sending or receiving data includes recording installation data 740 and shingle ID data in a roof database, such as the first server roof database. Likewise, in some versions, the step of sending or receiving data includes electronically reading data 760 from the first or second data field and transmitting 770 a record containing the data and installation location data to a roof database. In some versions, sending and receiving data includes receiving data from a subset of the fields of a roof data record.

Some versions have method steps in which the software retrieves user data from the roof database. User data can be data for a manufacturer, a roofer or an installer, an insurance adjuster, an appraiser, a homeowner, or a homebuyer. In some versions, the ID tag is designed to remain attached to the structure for 10-30 years.

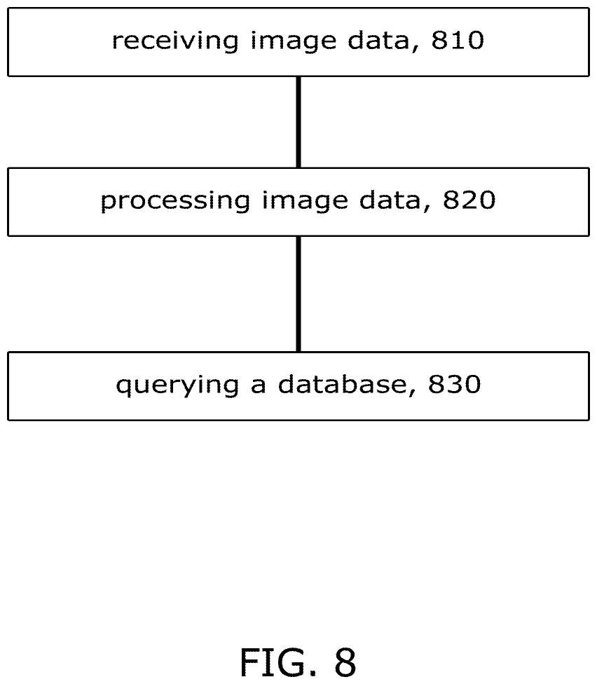

FIG. 8 depicts an alternative method having a step of receiving image data 810 from, for example, PI ID Tag 280. A step of processing image data 820 is used to retrieve usable data from the image. The usable data forms part of a query to a roof database in the querying a roof database step 830. For instance, a user such as described above would scan PI ID Tag 280 using software and hardware on electronic device 160. The software on electronic device 160 processes the scanned image data and extracts information from the data. The software constructs a query using some of the information and transmits that query using wireless hardware on electronic device 160. In some versions, the software accepts user input concerning the roof database information needed at that time and combines the user input with the information to construct the query.

An insurance adjuster may need different information than a house appraiser. Therefore, the software would construct the query to return roof database information useful to the adjuster and linked to the information from the scanned image data.

What is claimed is:

1. A shingling kit comprising:
a first ID tag containing a first data field;
a permanently installable ID tag containing a second data field;
and
shingles for a structure inside the kit.

2. The kit of claim 1 wherein the first data field includes data representing a link to a first server database containing data about the shingles.

3. The kit of claim 2, wherein the second data field includes data representing a link to a second server database containing data about the shingles.

4. The kit of claim 3, wherein the first server database and the second server database are the same database.

5. The kit of claim 4, wherein the primary ID tag is located on the kit.

6. A method comprising providing the kit of claim 1.

7. The method of claim 6 further comprising providing software to an end-user electronic device wherein the software facilitates a step of sending or receiving data from or to a first server database.

8. The method of claim 7, wherein sending or receiving data includes recording installation data and shingle ID data in a database.

9. The method of claim 8, wherein sending or receiving data includes electronically reading data from the first or second data field and transmitting a record containing the data and installation location data to a roof database.

10. The method of claim 9, wherein sending or receiving data includes receiving data from a subset of the fields of a roof data record.

11. The method of claim 10 further comprising providing software that retrieves user data from the roof database.

12. The method of claim 11 wherein the user is a manufacturer, a roofer or an installer, an insurance adjuster, an appraiser, a homeowner, or a homebuyer.

13. The method of claim 12, wherein the permanently installable ID tag is designed to remain attached to the structure for 10-30 years.

14. The method of claim 13, wherein the permanently installable ID tag is designed to remain attached to the structure for 10 years.

15. The method of claim 9 further comprising providing software that retrieves user data from the roof database.

16. The method of claim 15 wherein the user is a manufacturer, a roofer or an installer, an insurance adjuster, an appraiser, a homeowner, or a homebuyer.

17. The method of claim 16, wherein the permanently installable ID tag is designed to remain attached to the structure for 10-30 years.

18. The method of claim 17, wherein the permanently installable ID tag is designed to remain attached to the structure for 10 years.

19. A method of determining the age of a roof comprising:
using one or more processors to receive image data from an id tag for the roof;
processing the image data to extract an identification number for the installation of the roof;
and
querying a roof database containing information about the installation to extract the date of installation.

20. The method of claim 19 further comprising querying the roof database to extract information about shingles installed on the roof.
